(19) United States
(12) Patent Application Publication
(10) Pub. No.: US 2024/0186116 A1
(43) Pub. Date: Jun. 6, 2024

(54) METAL PART AND PROCESS CHAMBER HAVING THE SAME

(71) Applicant: POINT ENGINEERING CO., LTD., Chungcheongnam-do (KR)

(72) Inventors: Bum Mo AHN, Gyeonggi-do (KR); Young Heum EOM, Gyeonggi-do (KR); Tae Hwan SONG, Gyeonggi-do (KR)

(73) Assignee: POINT ENGINEERING CO., LTD., Chungcheongnam-do (KR)

(21) Appl. No.: 18/373,279

(22) Filed: Sep. 27, 2023

(30) Foreign Application Priority Data
Sep. 29, 2022 (KR) 10-2022-0124712

(51) Int. Cl. H01J 37/32; C23C 16/455; C25D 11/18

(52) U.S. Cl. CPC H01J 37/3244; C23C 16/45563; C25D 11/18; H01J 2237/3321; H01J 2237/3323

(57) ABSTRACT

Proposed are a metal part used in a display or semiconductor manufacturing process and a process chamber having the part. More particularly, proposed are a metal part that enables a film of uniform thickness to be formed on a surface of a substrate to be processed due to high emissivity thereof, and a process chamber having the same.

### FIELD OF THE INVENTION

The present disclosure relates to a metal component used in a display or semiconductor manufacturing process, and a process chamber having the metal component.

### DESCRIPTION OF THE RELATED ART

A process chamber is equipment in which a process of forming a thin film on a surface of a substrate to be processed is carried out using a process gas introduced therein. The process chamber performs the formation of the thin film using chemical vapor deposition (CVD).

This process chamber is provided with a metal component that performs a gas injection function to uniformly supply the process gas introduced into the process chamber onto the surface of the substrate to be processed.

The metal component has gas injection holes formed at regular intervals. The metal component is installed above the substrate to be processed in the process chamber so that they face each other, and sprays the process gas onto the substrate to be processed through the gas injection holes.

The deposition process proceeds with applying RF power to a reaction vessel to transfer heat to the substrate to be processed, which is placed on a support (susceptor) in which a heater is embedded, while maintaining vacuum conditions in the process chamber; and then supplying the process gas through the metal component while maintaining a plasma state to obtain a desired film. The deposition process is carried out at a high temperature of above 300° C.

However, when the temperature of the substrate to be processed or the surrounding area of the substrate to be processed is not uniform, a problem arises in that the thickness of the film formed on the surface of the substrate to be processed is not uniform.

The foregoing is intended merely to aid in the understanding of the background of the present disclosure, and is not intended to mean that the present disclosure falls within the purview of the related art that is already known to those skilled in the art.

### DOCUMENTS OF RELATED ART

### Patent Documents

(Patent document 1) Japanese Patent No. 1997-320799A

### DISCLOSURE

### Technical Problem

Accordingly, the present disclosure has been made keeping in mind the above problems occurring in the related art, and ab objective of the present disclosure is to provide a metal component and a process chamber having the metal component that increase the emissivity to make the temperature of a substrate to be processed or the surrounding area of the substrate to be processed uniform, thereby enabling a film of uniform thickness to be formed on a surface of the substrate to be processed.

### Technical Solution

In order to achieve the above objective, according to one aspect of the present disclosure, there is provided a metal component provided in a process chamber into which a process gas is introduced, the metal component including: a metal body; and a radiation layer provided on a surface of the metal body.

In addition, the radiation layer may include at least one of tin (Tin), titanium dioxide (TiOx), and chromium oxide (CrOx).

In addition, the metal component may further include: a protection layer provided on a surface of the radiation layer. Here, the radiation layer may be provided between the metal body and the protection layer.

In addition, the metal component may further include: an anodic aluminum oxide layer between the metal body and the radiation layer.

In addition, the anodic aluminum oxide layer may include at least one of a barrier layer and a porous layer having pores.

In addition, the anodic aluminum oxide layer may include a porous layer having pores, and the radiation layer may be formed inside each of the pores.

In addition, the metal component may be a diffuser having a gas injection hole.

In addition, the radiation layer may have an emissivity of 0.56 to 0.88.

According to another aspect of the present disclosure, there is provided a process chamber, including: a metal component including a metal body; and a radiation layer provided on a surface of the metal body. Here, the metal component may be provided in communication with an inside of the process chamber into which a process gas is introduced.

### Advantageous Effects

The metal component according to the present disclosure can have high emissivity through provision of the radiation layer. Due to high emissivity thereof, the metal component can serve to compensate for temperature when a temperature difference occurs between the upper and lower areas of the substrate to be processed, thereby resolving the temperature difference between the upper and lower areas of the substrate to be processed, and making the temperature of the substrate to be processed itself and the surrounding area of the substrate to be processed uniform. This enables a film of uniform thickness to be formed on the surface of the substrate to be processed. As a result, the yield of finished products manufactured by the process chamber having the metal component according to the present disclosure can be improved.

### BRIEF DESCRIPTION OF THE DRAWINGS

FIG. 1 is a view schematically illustrating a process chamber according to an embodiment of the present disclosure.

FIG. 2 is a view schematically showing a metal component according to a first embodiment of the present disclosure.

FIG. 3 is an enlarged view illustrating a portion of the metal component illustrated in FIG. 2.

FIG. 4 is an enlarged view illustrating a portion of a metal component according to a second embodiment of the present disclosure.

FIG. 5 is an enlarged view illustrating a portion of a metal component according to a third embodiment of the present disclosure.

### DETAILED DESCRIPTION OF THE INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, widths and thicknesses of regions in the figures may be exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing.

Hereinafter, exemplary embodiments of the present disclosure will be described in detail with reference to the accompanying drawings.

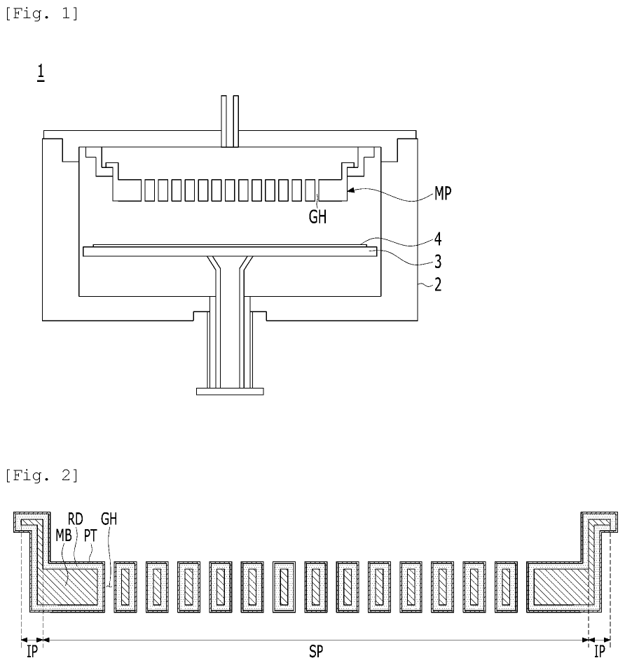

FIG. 1 is a view schematically illustrating a process chamber 1 according to an embodiment of the present disclosure.

The process chamber 1 according to the embodiment of the present disclosure may be semiconductor manufacturing process equipment or display manufacturing process equipment.

The process chamber 1 according to the embodiment of the present disclosure will be hereinafter described as chemical vapor deposition (CVD) equipment used in a semiconductor or display manufacturing process.

As illustrated in FIG. 1, the process chamber 1 according to the present disclosure includes a reaction vessel 2 accommodating a substrate to be processed 4, therein, a support 3 installed in a lower space in the reaction vessel 2 and supporting the substrate to be processed 4, and a metal component MP provided above the support 3 to face the support 3.

When the process chamber 1 according to the present disclosure is CVD equipment, the reaction vessel 2 provides a space for installing the support 3 and the metal component MP, the substrate to be processed 4 is a wafer or glass, the support 3 that supports the substrate to be processed 4 is a susceptor provided with an embedded heater therein, and the metal component MP is a diffuser that has a plurality of gas injection holes GH and sprays a process gas introduced into the reaction vessel 2.

The process chamber 1 according to the present disclosure receives a process gas from an external gas supplier into the reaction vessel 2 through a process line connected to the process chamber 1. The process chamber 1 performs a process of depositing a film on a surface of the substrate to be processed 4 by spraying the process gas supplied therein through the metal component MP to the substrate to be processed 4.

The process chamber 1 according to the present disclosure is provided with the metal component MP having a radiation layer RD so that a film of uniform thickness is formed on the surface of the substrate to be processed 4.

The metal component MP provided in the process chamber 1 according to the present disclosure includes metal components MP according to first to third embodiments of the present disclosure illustrated in FIGS. 2 to 5, and may be at least one of the metal components MP according to the three embodiments.

In the process chamber 1 according to the present disclosure, by providing at least one of the metal components MP according to the first to third embodiments having high emissivity imparted by the radiation layer RD, a film of uniform thickness can be formed on the surface of the substrate to be processed 4.

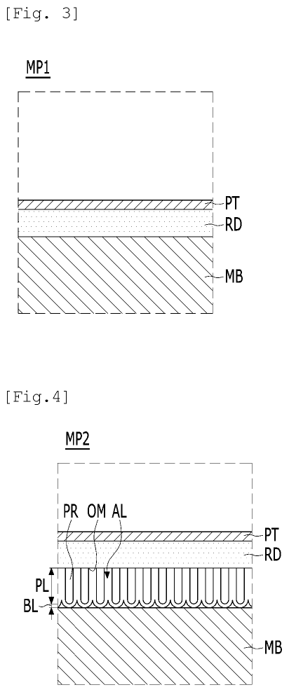

First, a metal component MP1 according to the first embodiment of the present disclosure will be described in detail with reference to FIGS. 2 and 3. In FIGS. 2 and 3, the thicknesses of a radiation layer RD and a protection layer PT are exaggerated compared to the actual thicknesses for convenience of illustration.

As illustrated in FIG. 2, the metal component MP1 according to the first embodiment includes a metal body MB made of a metal material and the radiation layer RD provided on a surface of the metal body MB.

The metal body MB includes a spray portion SP in which a plurality of gas injection holes GH are formed at regular intervals, and an installation portion IP extending upwardly from each side of the spray portion SP. As an example, an upper end of the installation portion IP is bent outwardly. The metal body MB is assembled and installed to a metal body MB coupling portion provided in the process chamber 1 through the installation portion IP.

The metal component MP1 according to the first embodiment communicates with the inside of the process chamber 1 through the plurality of gas injection holes GH while being installed to the metal body MB coupling portion inside the process chamber 1. Thus, the metal component MP1 according to the first embodiment sprays a process gas introduced into the process chamber 1 through the gas injection holes GH.

The metal body MB is made of a metal material. The metal material includes aluminum, titanium, tungsten, zinc, and an alloy of these metals.

The radiation layer RD is formed entirely on the surface of the metal body MB. More specifically, the radiation layer RD is formed entirely on the surface including upper and lower surfaces and opposite outer surfaces of the metal body MB.

The radiation layer RD may be formed on the surface of the metal body MB using a chemical vapor deposition (CVD) method or a carbon coating method. The radiation layer RD is preferably formed to have a thickness of equal to or less than 1 μm.

The radiation layer RD includes at least one of tin (Tin), titanium dioxide (TiOx), and chromium oxide (CrOx).

As the metal component MP1 according to the first embodiment is provided with the radiation layer RD on the surface of the metal body MB, the temperature of the substrate to be processed 4 or the surrounding area (specifically, the upper area) of the substrate to be processed 4 can be made uniform.

In detail, the temperature of the substrate to be processed 4 is increased by application of heat from a heater embedded in a support 3. Here, the lower area including a lower surface of the substrate to be processed 4 receives heat while in direct contact with an upper surface of the support 3 and has a relatively high temperature, while the upper area including an upper surface of the substrate to be processed 4 has a relatively low temperature.

In other words, a temperature difference occurs between the lower area and the upper area of the substrate to be processed 4. When the temperature of the substrate to be processed 4 is not uniform, the thickness of a film formed on a surface of the substrate to be processed 4 is not uniform. As a result, a problem arises in that the thickness of the film on one portion of the surface of the substrate to be processed 4 is thicker or thinner than that of the film on another portion of the surface of the substrate to be processed 4.

The metal component MP1 according to the first embodiment has high emissivity relative to the upper area of the substrate to be processed 4 by providing the radiation layer RD. The metal component MP1 according to the first embodiment sprays the process gas onto the surface of the substrate to be processed 4 in a state where a lower surface thereof is close to the upper surface of the substrate to be processed 4. Here, since the metal component MP1 according to the first embodiment has high emissivity imparted by the radiation layer RD, the amount of heat radiated from the lower surface of the metal component MP1 according to the first embodiment to the upper surface of the substrate to be processed 4 is high.

Thus, as the temperature of the surrounding area, including the upper area of the substrate to be processes 4, increases, the temperature of the upper area, including the upper surface of the substrate to be processed 4, increases.

By providing the radiation layer RD, the metal component MP1 according to the first embodiment has high emissivity. Specifically, the radiation layer RD has an emissivity of 0.56 to 0.88.

Thus, the metal component MP1 according to the first embodiment can serve to compensate for temperature when a temperature difference occurs between the upper and lower areas of the substrate to be processed 4, thereby resolving the temperature difference between the upper and lower areas of the substrate to be processed 4.

As the temperature of the upper area of the substrate to be processed 4 and the temperature around the upper area of the substrate to be processed 4 increase due to the metal component MP1 according to the first embodiment, the temperature of the substrate to be processed 4 itself and the temperature of the surrounding area of the substrate to be processed 4 are made uniform. As a result, the film formed on the surface of the substrate to be processed 4 through a deposition process can have a uniform thickness.

In the metal component MP1 according to the first embodiment, the radiation layer RD is formed in the form of a thin film on the surface of the metal body MB. Therefore, a means for increasing the emissivity without occupying a large volume may be provided.

To increase the emissivity, it may be considered to install a heater inside a metal component that performs the function of spraying gas. This method is difficult to implement in metal components in which a plurality of gas injection holes are formed at a narrow pitch because a separate space for installing the heater is needed.

However, the metal component MP1 according to the first embodiment is provided with the radiation layer RD formed in the form of a thin film on the metal body MB using a CVD method or a carbon coating method. Thus, the metal component MP1 according to the first embodiment can have high emissivity without requiring a separate installation space for the means for increasing the emissivity and without occupying a large volume.

Unlike the metal component MP1 according to the first embodiment, it was confirmed through experiment that when only a metal body MD made of aluminum or aluminum alloy is provided without a radiation layer RD on a surface of the metal body MD, an emissivity of 0.17 to 0.18 was exhibited.

Meanwhile, it was confirmed that the metal component MP1 according to the first embodiment had an emissivity of 0.56 to 0.88 through provision of the radiation layer RD on the surface of the metal body MD.

As described above, in the metal component MP1 according to the first embodiment, by providing the thin and high-emissivity radiation layer RD on the surface of the metal body MD having relatively low emissivity, the emissivity can be improved compared to a structure including only the metal body MD.

The metal component MP1 according to the first embodiment has a protection layer PT on a surface of the radiation layer RD.

The protection layer PT may be formed by alternately supplying a precursor gas that is at least one of aluminum, silicon, hafnium, zirconium, yttrium, erbium, titanium, and tantalum, and a reactant gas that can form a film constituting the protection layer PT. More specifically, the protection layer PT is formed by repeatedly performing a cycle of adsorbing the precursor gas to the surface of the radiation layer RD and supplying the reactant gas to generate a monoatomic layer through chemical substitution of the precursor gas and the reactant gas.

Each time the cycle is performed, a thin monoatomic layer is formed. The protection layer PT is formed by repeatedly performing the cycle and is composed of a plurality of monoatomic layers. The protection layer PT is preferably formed to have a thickness of 1 nm to 500 nm.

Depending on the composition of the precursor gas and reactant gas, the protection layer PT may include at least one of an aluminum oxide layer, a yttrium oxide layer, a hafnium oxide layer, a silicon oxide layer, an erbium oxide layer, a zirconium oxide layer, a fluoride layer, a transition metal layer, a titanium nitride layer, a tantalum nitride layer, and a zirconium nitride layer.

In detail, when the protection layer PT is an aluminum oxide layer, the precursor gas may include at least one of aluminum alkoxide (Al(T-OC₄H₉)₃), aluminum chloride (AlCl₃), trimethyl aluminum (TMA: Al(CH₃)₃), diethylaluminum ethoxide, tris (ethylmethylamido) aluminum, aluminum sec-butoxide, aluminum tribromide, aluminum trichloride, triethyl aluminum, triisobutyl aluminum, trimethyl aluminum, and tris (diethylamido) aluminum.

Here, when at least one of aluminum alkoxide (Al(T-OC₄H₉)₃), diethylaluminum ethoxide, tris (ethylmethylamido) aluminum, aluminum sec-butoxide, aluminum tribromide, aluminum trichloride, triethyl aluminum, triisobutyl aluminum, trimethyl aluminum, and tris (diethylamido) aluminum is used as the precursor gas, H₂O may be used as the reactant gas.

When aluminum chloride (AlCl₃) is used as the precursor gas, O₃ may be used as the reactant gas.

When trimethyl aluminum (TMA: Al(CH₃)₃) is used as the precursor gas, O₃ or H₂O may be used as the reactant gas.

When the protection layer P is an yttrium oxide layer, the precursor gas may include at least one of yttrium chloride (YCl₃), Y(C₅H₅)₃, tris (N,N-bis (trimethylsilyl) amide) yttrium(III), yttrium(III)butoxide, tris (cyclopentadienyl) yttrium(III), tris (butylcyclopentadienyl)yttrium(III), tris(2,2,6,6-tetramethyl-3,5-heptanedionato) yttrium(III), tris (cyclopentadienyl) yttrium (Cp₃Y), tris (methylcyclopentadienyl) yttrium ((CpMe)₃Y), tris(butylcyclopentadienyl)yttrium, and tris (ethylcyclopentadienyl) yttrium.

In this case, when at least one of yttrium chloride (YCl₃) and Y(C₅H₅)₃ is used as the precursor gas, O₃ may be used as the reactant gas.

When at least one of tris(N,N-bis (trimethylsilyl)amide)yttrium(III), yttrium(III)butoxide, tris (cyclopentadienyl) yttrium(III), tris (butylcyclopentadienyl)yttrium(III), tris(2,2,6,6-tetramethyl-3,5-heptanedionato) yttrium(III), tris (cyclopentadienyl) yttrium (Cp₃Y), tris (methylcyclopentadienyl) yttrium ((CpMe)₃Y), tris (butylcyclopentadienyl) yttrium, and tris(ethylcyclopentadienyl)yttrium is used as the precursor gas, at least one of H₂O, O₂, and O₃ may be used as the reactant gas.

When the protection layer PT is a hafnium oxide layer, the precursor gas may include at least one of hafnium chloride (HfCl₄), Hf(N(CH₃) (C₂H₅))₄, Hf(N(C₂H₅)₂)₄, tetra (ethylmethylamido) hafnium, and pentakis (dimethylamido) tantalum.

In this case, when at least one of hafnium chloride (HfCl₄), Hf(N(CH₃) (C₂H₅))₄, and Hf(N(C₂H₅)₂)₄ is used as the precursor gas, O₃ may be used as the reactant gas.

When at least one of tetra(ethylmethylamido)hafnium and pentakis (dimethylamido) tantalum is used as the precursor gas, at least one of H₂O, O₂, and O₃ may be used as the reactant gas.

When the protection layer PT is a silicon oxide layer, the precursor gas may include Si(OC₂H₅)₄. In this case, O₃ may be used as the reactant gas.

When the protection layer PT is an erbium oxide layer, the precursor gas may include at least one of tris-methylcyclopentadienyl erbium(III) (Er(MeCp)₃), erbium boranamide (Er(BA)₃), Er(TMHD)₃, erbium(III) tris (2,2,6,6-tetramethyl-3,5-heptanedionate), tris (butylcyclopentadienyl)erbium(III), tris(2,2,6,6-tetramethyl-3,5-heptanedionato) erbium (Er(thd)₃), Er(PrCp)₃, Er(CpMe)₂, Er(BuCp)₃, and Er(thd)₃.

In this case, when at least one of tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), and tris(butylcyclopentadienyl)erbium(III) is used as the precursor gas, at least one of H₂O, O₂, and O₃ may be used as the reactant gas.

When at least one of tris(2,2,6,6-tetramethyl-3,5-heptanedionato) erbium (Er(thd)₃), Er(PrCp)₃, Er(CpMe)₂, and Er(BuCp)₃ is used the precursor gas, O₃ may be used as the reactant gas.

When Er(thd)₃ is used as the precursor gas, an O-radical may be used as the reactant gas.

When the protection layer PT is a zirconium oxide layer, the precursor gas may include at least one of zirconium tetrachloride (ZrCl₄), Zr (T-OC₄H₉)₄, zirconium(IV) bromide, tetrakis (diethylamido) zirconium(IV), tetrakis (dimethylamido) zirconium(IV), tetrakis(ethylmethylamido)zirconium(IV), tetrakis(N,N′-dimethyl-formamidinate) zirconium, tetra(ethylmethylamido)hafnium, pentakis (dimethylamido) tantalum, tris(dimethylamino) (cyclopentadienyl)zirconium, and tris (2,2,6,6-tetramethyl-heptane-3,5-dionate) erbium.

When at least one of these components is used as the precursor gas, at least one of H₂O, O₂, O₃, and an O-radical may be used as the reactant gas.

When the protection layer PT is a fluorinated layer, the precursor gas may include tris(2,2,6,6-tetramethyl-3,5-heptanedionato) yttrium(III). In this case, at least one of H₂O, O₂, and O₃ may be used as the reactant gas.

When the protection layer PT is a transition metal layer, the precursor gas may include at least one of tantalum pentachloride (TaCl₅) and titanium tetrachloride (TiCl₄). In this case, an H-radical may be used as the reactant gas.

Specifically, when tantalum pentachloride (TaCl₅) is used as the precursor gas and the H-radical is used as the reactant gas, the transition metal layer may be a tantalum layer.

On the other hand, when titanium tetrachloride (TiCl₄) is used as the precursor gas and the H-radical is used as the reactant gas, the transition metal layer may be a titanium layer.

When the protection layer PT is a titanium nitride layer, the precursor gas may include at least one of bis (diethylamido)bis (dimethylamido) titanium(IV), tetrakis(diethylamido)titanium(IV), tetrakis (dimethylamido) titanium(IV), tetrakis (ethylmethylamido) titanium(IV), titanium(IV) bromide, titanium(IV) chloride, and titanium(IV) tert-butoxide. In this case, at least one of H₂O, O₂, O₃, and an O-radical may be used as the reactant gas.

When the protection layer PT is a tantalum nitride layer, the precursor gas may include at least one of pentakis (dimethylamido) tantalum (V), tantalum(V) chloride, tantalum(V) ethoxide, and tris(diethylamino) (tert-butylimido)tantalum(V). In this case, at least one of H₂O, O₂, O₃, and an O-radical may be used as the reactant gas.

When the protection layer PT is a zirconium nitride layer, the precursor gas may include at least one of zirconium(IV) bromide, zirconium(IV) chloride, zirconium(IV) tert-butoxide, tetrakis (diethylamido) zirconium(IV), tetrakis (dimethylamido) zirconium(IV), and tetrakis(ethylmethylamido)zirconium(IV). In this case, at least one of H₂O, O₂, O₃, and an O-radical may be used as the reactant gas.

As described above, the protection layer PT may be embodied as a variety of different types of protection layers depending on the constituent components of the precursor gas and the reactant gas.

When only the radiation layer RD is provided on the surface of the metal body MB, it may be advantageous in terms of having high emissivity, but the process gas used during a deposition process may cause the radiation layer RD to be easily corroded. In order to prevent this problem, the metal component MP1 according to the first embodiment is provided with the protection layer PT on the surface of the radiation layer RD to protect the radiation layer RD from the process gas and has corrosion resistance. The radiation layer RD is provided between the metal body MB and the protection layer PT and can function to increase the emissivity without being corroded by the process gas.

In the metal component MP1 according to the first embodiment, since the radiation layer RD is provided on the surface of the metal body MB and the protection layer PT is provided on the surface of the radiation layer RD, the radiation layer RD is covered by the protection layer PT without being exposed to the outside. In other words, the protection layer PT is provided to cover the radiation layer RD on the surface of the radiation layer RD.

The process chamber 1 provided with the metal component MP1 according to the first embodiment performs a deposition process using the process gas. The process gas is a gas in a plasma state and has strong corrosive and erosive properties. When the radiation layer RD comes into direct contact with plasma, problems such as corrosion and erosion may occur.

In the metal component MP1 according to the first embodiment, the protection layer PT is provided on the surface of the radiation layer RD and the radiation layer RD is covered by the protection layer PT. With this, during the process of forming a film on the surface of the substrate to be processed 4, the metal component MP1 according to the first embodiment can perform the process without undergoing corrosion or erosion due to the process gas, and enables a film of uniform thickness to be formed on the surface of the substrate to be processed 4 due to high emissivity thereof imparted by the radiation layer RD.

In other words, through provision of the radiation layer RD and the protection layer PT, the metal component MP1 according to the first embodiment can have corrosion resistance and high emissivity at the same time, so that it can more effectively perform the process of forming a film of uniform thickness on the surface of the substrate to be processed 4.

In the process chamber 1 according to the present disclosure, by providing the metal component MP1 having high emissivity imparted by the radiation layer RD, a film of uniform thickness can be formed on the surface of the substrate to be processed 4. As a result, the yield of finished products manufactured by the process chamber 1 according to the present disclosure can be improved.

FIG. 4 is an enlarged view schematically illustrating a portion of a metal component MP2 according to the second embodiment of the present disclosure.

The metal component MP2 according to the second embodiment differs from the metal component MP1 according to the first embodiment in that it includes an anodic aluminum oxide layer AL between a metal body MB and a radiation layer RD. The embodiments described below will be mainly described in terms of characteristic elements in comparison with the metal component MP1 according to the first embodiment, and descriptions of the same or similar elements thereto will be omitted.

Referring to FIG. 4, the anodic aluminum oxide layer AL is provided on a surface of the metal body MB.

The anodic aluminum oxide layer AL is formed on the surface of the metal body MB by anodizing a base material, which is a metal constituting the metal body MB.

The anodic aluminum oxide layer AL includes a barrier layer BL in which no pores PR are formed therein, and a porous layer PL in which pores PR are formed therein. The barrier layer BL is located on top of the base material, that is, the metal body MB, and the porous layer PL is located on top of the barrier layer BL. In this case, the anodic aluminum oxide layer AL has a side open by openings OM of the pores PR of the porous layer PL.

The barrier layer BL is preferably formed to have a thickness of hundreds of nm, and more preferably 100 nm to 1 μm.

The porous layer PL has a thickness of tens of μm to hundreds of μm. The pores PR have a diameter of several nm to hundreds of nm.

The anodic aluminum oxide layer AL may have a structure including the barrier layer BL and the porous layer PL. In this case, the anodic aluminum oxide layer AL is provided so that the barrier layer BL is located on top of the metal body MB and the porous layer PL is located on top of the barrier layer BL. The porous layer PL is located on top of the barrier layer BL, and has a side (specifically, a surface side) open by the openings OM of the pores PR. In the metal component MP2 according to the second embodiment, the anodic aluminum oxide layer AL is provided on the surface of the metal body MB and the radiation layer RD is provided on the surface of the anodic aluminum oxide layer AL open by the porous layer PL. The surface of the anodic aluminum oxide layer AL is closed by the radiation layer RD. The radiation layer RD may be formed on the surface of the anodic aluminum oxide layer AL by a CVD method or a carbon coating method. The radiation layer RD may be formed along the surface of the anodic aluminum oxide layer AL to cover the entire surface of the anodic aluminum oxide layer AL.

Meanwhile, the metal component MP2 according to the second embodiment may be provided with an anodic aluminum oxide layer AL including a barrier layer BL. In this case, the anodic aluminum oxide layer AL has a structure in which only the barrier layer BL exists without a porous layer PL on top of the barrier layer BL.

In the metal component MP2 according to the second embodiment, the barrier layer BL having no pores PR is formed entirely along the surface of the metal body MB, and the radiation layer RD is formed along the surface of the barrier layer BL.

The radiation layer RD may be formed by a CVD method or a carbon coating method. When the radiation layer RD is formed by the CVD method, the radiation layer RD is deposited with a predetermined thickness on the openings OM of the pores PR and the surface of the porous layer PL existing around the openings OM of the pores PR, while closing the openings OM of the pores PR.

When the radiation layer RD is formed by the carbon coating method, the radiation layer RD is formed in the form of a film that closes the surface of the anodic aluminum oxide layer AL open by the pores PR of the porous layer PL.

Meanwhile, the metal component MP2 according to the second embodiment may be provided with an anodic aluminum oxide layer AL including a porous layer PL. In this case, the anodic aluminum oxide layer AL has a structure in which only the porous layer PL in which vertical pores PR having open top and bottom ends are formed exists as a barrier layer BL located under the porous layer PL is removed by a method such as etching.

As the anodic aluminum oxide layer AL having a first surface and a second surface open by the pores PR is formed on the surface of the metal body MB, the open first surface thereof is closed by the surface of the metal body MB. As the radiation layer RD is formed on the surface of the anodic aluminum oxide layer AL, the open second surface of the anodic aluminum oxide layer AL is closed by the radiation layer RD. The radiation layer RD may be formed by a CVD method or a carbon coating method.

In the metal component MP2 according to the second embodiment, the anodic aluminum oxide layer AL is provided on the surface of the metal body MB, the radiation layer RD is provided on the surface of the anodic aluminum oxide layer AL, and a protection layer PT is provided on a surface of the radiation layer RD. That is, the anodic aluminum oxide layer AL, the radiation layer RD, and the protection layer PT are sequentially formed on the surface of the metal body MB. With this, the metal component MP2 according to the second embodiment has high emissivity.

Unlike the metal component MP2 according to the second embodiment, it was confirmed through experiment that a structure including an anodic aluminum oxide layer AL on a surface of a metal body MB had an emissivity of 0.21 to 0.23.

Meanwhile, it was confirmed that the metal component MP2 according to the second embodiment had an emissivity of 0.56 to 0.88 through provision of the radiation layer RD on the surface of the anodic aluminum oxide layer AL.

As described above, due to high emissivity thereof imparted by forming the radiation layer RD on the surface of the anodic aluminum oxide layer AL having relatively low emissivity, the metal component MP2 according to the second embodiment enables a film of uniform thickness to be formed on a surface of a substrate to be processed 4.

In the metal component MP2 according to the second embodiment, the radiation layer RD is provided between the anodic aluminum oxide layer AL and the protection layer PT. The anodic aluminum oxide layer AL functions to prevent corrosion. By having a structure in which the anodic aluminum oxide layer AL is provided on a first surface of the radiation layer RD and the protection layer PT is provided on a second surface thereof, the metal component MP2 according to the second embodiment can have high corrosion resistance and high emissivity at the same time, enabling a film of uniform thickness to be formed on the surface of the substrate to be processed 4.

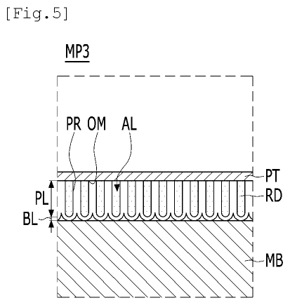

FIG. 5 is an enlarged view illustrating a portion of a metal component MP3 according to the third embodiment of the present disclosure.

The metal component MP3 according to the third embodiment differs from the metal components MP1 and MP2 according to the first and second embodiments in that an anodic aluminum oxide layer AL is provided between a metal body MB and a radiation layer RD and the radiation layer RD is formed inside pores PR. The embodiments described below will be mainly described in terms of characteristic elements in comparison with the metal components MP1 and MP2 according to the first and second embodiments, and descriptions of the same or similar elements thereto will be omitted.

Referring to FIG. 5, the anodic aluminum oxide layer AL is provided on a surface of the metal body MB.

The anodic aluminum oxide layer AL may include a barrier layer BL and a porous layer PL. In this case, the anodic aluminum oxide layer AL is provided so that the barrier layer BL is located on top of the metal body MB and the porous layer PL is located on top of the barrier layer BL.

The radiation layer RD is formed by filling an empty space inside each of the pores PR. In this case, the radiation layer RD is preferably formed using a sealing method that fills empty spaces of holes.

When forming the radiation layer RD inside each of the pores PR, the pores PR are preferably formed to have a longitudinal thickness of 11 μm to 3 μm.

The radiation layer RD is formed inside each of the pores PR with a diameter of several nm to hundreds of nm and is provided in the form of a rod having a longitudinal thickness.

In the metal component MP3 according to the third embodiment, as the radiation layer RD is formed inside each of the pores PR, long rod-shaped radiation layers RD are provided on the surface of the metal body MB.

An opening OM of each of the pores PR is closed by the radiation layer RD that fills the empty space inside the pore PR. One surface of the radiation layer RD is exposed to the outside through the opening OM of the pore PR.

Meanwhile, the metal component MP3 according to the third embodiment may be provided with an anodic aluminum oxide layer AL including a porous layer PL on the surface of the metal body MB. In this case, the anodic aluminum oxide layer AL provided on the surface of the metal body MB has a structure in which only the porous layer PL in which pores PR having open top and bottom ends are formed exists as a barrier layer BL located under the porous layer PL is removed. In the anodic aluminum oxide layer AL, at least one of a first side opening or a second side opening of each of the pores PR is closed by the surface of the metal body MB. In the metal component MP3 according to the third embodiment, the radiation layer RD is formed inside each of the pores PR of the anodic aluminum oxide layer AL in which first side openings of the pores PR are closed by the metal body MB. The second side opening of each of the pores PR is closed by the radiation layer RD that fills the empty space inside the pore PR.

In the metal component MP3 according to the third embodiment, the radiation layer RD is provided inside each of the pores PR and a protection layer PT is provided on surfaces of the respective radiation layers RD. The protection layer PT is formed on the surfaces of the radiation layers RD by the same method as described above for the metal component MP1 according to the first embodiment.

Referring to FIG. 5, the protection layer PT is formed on top of the radiation layers RD provided inside the pores PR and located at positions corresponding to the openings OM of the pores PR. More specifically, in the metal component MP3 according to the third embodiment, as the radiation layers RD are provided inside the pores PR before the protection layer PT is provided, one side (surface) of the porous layer PL existing around the openings OM of the pores PR and one sides (surfaces) of the radiation layers RD located at positions corresponding to the openings OM of the pores PR are exposed to the outside. In the metal component MP3 according to the third embodiment, the radiation layers RD are provided inside the pores PR and the protection layer PT is provided on a surface of the anodic aluminum oxide layer AL.

Thus, the protection layer PT is formed on the surface of the anodic aluminum oxide layer AL and on top of the porous layer PL while covering the one side (surface) of the porous layer PL existing around the openings OM of the pores PR and the one sides (surfaces) of the radiation layers RD located at positions corresponding to the openings OM of the pores PR.

In the metal component MP3 according to the third embodiment, as the radiation layers RD are provided inside the pores PR of the anodic aluminum oxide layer AL, the radiation layers RD are provided between the anodic aluminum oxide layer AL and the protection layer PT or between the metal body MB and the protection layer PT.

The metal component MP3 according the third embodiment has emissivity by providing the radiation layers RD inside the pores PR of the anodic aluminum oxide layer AL. Thus, in the metal component MP3 according to the third embodiment, by providing the radiation layers RD without requiring provision of a separate space for installing a means for performing the radiation function, a film of a uniform thickness can be formed on the surface of a substrate to be processed 4.

In addition, through provision of the radiation layers between the anodic aluminum oxide layer AL and the protection layer PT, the metal component MP3 according to the third embodiment can have high corrosion resistance, so that it can effectively perform a deposition process without undergoing corrosion.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

Description of the Reference Numerals in the Drawings

| | |
|---|---|
| 1: process chamber | |
| 2: reaction vessel | 3: support |
| 4: substrate to be processed | |
| MP: metal component | |
| MB: metal body | |
| SP: spray portion | IP: installation portion |
| GH: gas injection hole | |
| RD: radiation layer | PT: protection layer |
| AL: anodic aluminum oxide layer | |
| BL: barrier layer | PL: porous layer |
| PR: pore | |

What is claimed is:

1. A metal part provided in a process chamber into which a process gas is introduced, the metal part comprising:
a metal body; and
a radiation layer provided on a surface of the metal body.

2. The metal part of claim 1, wherein the radiation layer includes at least one of tin (Tin), titanium dioxide (TiOx), and chromium oxide (CrOx).

3. The metal part of claim 1, further comprising:
a protection layer provided on a surface of the radiation layer, wherein the radiation layer is provided between the metal body and the protection layer.

4. The metal part of claim 1, further comprising:
an anodic aluminum oxide layer between the metal body and the radiation layer.

5. The metal part of claim 4, wherein the anodic aluminum oxide layer includes at least one of a barrier layer and a porous layer having pores.

6. The metal part of claim 4, wherein the anodic aluminum oxide layer includes a porous layer having pores, and the radiation layer is formed inside each of the pores.

7. The metal part of claim 1, wherein the metal part is a diffuser having a gas injection hole.

8. The metal part of claim 1, wherein the radiation layer has an emissivity of 0.56 to 0.88.

9. A process chamber, comprising:
a metal part including a metal body; and
a radiation layer provided on a surface of the metal body,
wherein the metal part is provided in communication with an inside of the process chamber into which a process gas is introduced.
